(19) United States
(12) Patent Application Publication
(10) Pub. No.: US 2007/0096309 A1
(43) Pub. Date: May 3, 2007

(54) Semiconductor device, method of forming wiring pattern, and method of generating mask wiring data

(75) Inventor: Yoshihisa Matsubara, Ibaraki (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/590,846

(22) Filed: Nov. 1, 2006

(30) Foreign Application Priority Data
Nov. 2, 2005 (JP) 2005-319578

(51) Int. Cl. H01L 23/48

(52) U.S. Cl. 257/734

(57) ABSTRACT

A semiconductor device includes a first wiring portion and a second wiring portion. The first wiring portion is configured to include a plurality of fine wirings placed densely. The second wiring portion configured to include a wiring, which is connected to one of the plurality of fine wirings in the same wiring layer, and of which outside dimension is larger than that of the one of the plurality of fine wirings. The wiring of the second wiring portion is composed of a peripheral wiring which circles an outer periphery of the wiring.

### BACKGROUND OF THE INVENTION

1. Field of the Invention

The present invention relates to a semiconductor device having two or more wiring layers, a method of forming a wiring pattern for the semiconductor device, and a method of generating a mask wiring data for the semiconductor device.

2. Description of the Related Art

The background techniques of the present invention are described by exemplifying a typical test pattern for a process evaluation in a semiconductor device with reference to a document entitled “Advanced Process Technology 2003, Backend Process: Section 5. 200 nm pitch double layer Cu interconnection TEG and module results”, available from a website of URL: “http://www.selete.co.jp/SeleteHPJ1/j_html/research/ma in034.html”, search date is Oct. 26, 2005. FIG. 1 is a schematic view showing an entire layout of a test block (chip) for a typical process evaluation. The maximum values of a lateral width 701 and a longitudinal width 702 of the test block are typically defined in a field size of a lithography apparatus. The test block for the process evaluation is configured by a set of evaluation blocks referred to as sub chips 703. The sizes of the respective sub chips 703 are equally inside the test block, This reason is that, since setting and moving of a measuring probe become equal in respective measuring programs, the program and the measuring probe can be shared.

As a test pattern for wiring process evaluation, there are a via chain, an electromigration test pattern, a leak measurement pattern and the like. In the via chain, the pattern scale is generally changed on the basis of the length of the wiring to be evaluated and the number of the vias. By changing this pattern scale, it is also possible to evaluate a defect density. FIG. 2 is a schematic view showing a part of the test pattern for the wiring process evaluation. As shown in FIG. 2, this test pattern has: a process evaluation block which is referred to as a TEG (Test Element Group) region 801; and a pad portion 802 which is a region including wiring electrodes with which an electrical measurement needle (probe) is brought into contact. Vias 803 entirely exist in the wiring electrodes in this pad portion 802. A macro circuit (hereafter, referred to as a TEG macro) in the TEG region 801 and the wiring electrodes in the pad portion 802 are connected through a wiring referred to as a lead-out wiring 804. A distance 805 between the TEG macro and the lead-out wiring 804 is about 2 μm (micrometer), and a distance 806 between the TEG macro and the pad portion 802 is about 50 μm.

FIG. 3 is a graph showing a relation between a wiring pitch and a wiring width (CD). The horizontal axis shows the wiring pitch, and the vertical axis shows the wiring width (CD). In the photolithography technology, an isolated wiring portion, where density of wiring (isolated wiring) is relatively low, has a problem of a drop in an exposure light intensity. For this reason, as shown in FIG. 3, as the wiring pitch is wider, the wiring width (CD) tends to be narrower. In order to avoid this problem, in the isolated wiring, the wiring whose width is varied to be wider in a stepped manner is typically used for a portion where the isolated wiring becomes in the isolated state from a dense pattern. This example will be described below with reference to FIG. 4.

FIG. 4 is an enlarged plan view showing a lead-out wiring and a TEG region in the test pattern for the via chain evaluation. A lead-out wiring 1002, through which the pad portion (not shown) is electrically connected to a TEG region 1001 for the via chain evaluation, is placed from the TEG region 1001 to outside. The via chain portion formed in the TEG region 1001 has a two-layer wiring structure where M1 wirings (first layer wirings) 1003 and M2 wirings (second layer wirings) 1004 are alternately placed in a lower layer and an upper layer, respectively, and those wirings are connected through vias (not shown). The lead-out wiring 1002 is connected in the same wiring layer to one M1 wiring 1003 of the TEG region 1001. The M1 wiring 1003 of the TEG region 1001 is formed such that the wiring width is wider in the stepped manner, as indicated by a reference letter 1006, at the stage where it is connected to the lead-out wiring 1002. A reference letter 1009 indicates a connection distance between this wide wiring portion 1006 and the TEG region 1001.

Next, a method for forming the typical two-layer wirings is explained. FIGS. 5A to 5E are sectional views showing main steps of the method for forming the typical two-layer wiring.

At first, a first inter-layer insulating film 1102, which is composed of silicon oxide film and the like, is formed on a silicon substrate 1101 by using a CVD method or the like (FIG. 5A). After that, a first photolithography resist 1103 is formed on this first inter-layer insulating film 1102, and then, the first photolithography resist 1103 is patterned by using a first photolithography method (FIG. 5B). Moreover, after this resist pattern is transcribed into the first inter-layer insulating film 1102 by using a dry etching technique, and then, the first photolithography resist 1103 is removed, thereby forming wiring trenches 1104 at a desirable position (FIG. 5C).

Next, a conductive film 1105 composed of copper, aluminum and the like is formed on the entire surface of the first inter-layer insulating film 1102 including the wiring trenches 1104 (trenches 1104a and 1104b) by using the CVD method and the like (FIG. 5D) Then, the surface of the conductive film 1105 is flattened by using the CMP method. As this result, first wirings 1106 (first wirings 1106a and 1106b)of a damocene wiring structure is formed at a desirable position of the first inter-layer insulating film 1102 (FIG. 5E).

Next, the conventional configuration of a typical CPU logic circuit will be described below. The structure of a connection wiring to an electrically and densely crowded circuit block from a certain isolating circuit block is described with reference to this conventional example, because the similar structure is used not only in the TEG lead-out wiring for the process evaluation but also in products.

FIG. 6 is a schematic view showing the typical CPU logic circuit. This CPU logic circuit is provided with four macros of I/O blocks 1201, RAM blocks 1202, a logic block 1203 and a PLL block 1204.

In FIG. 6, the I/O block 1201 is an area constituted by only wirings having a wiring width of 1 μm or more. Basically, there is no need of a narrow wiring. In an area where an allowable capacity limit on a large current is determined, the maximum value of the wiring width and a via diameter is determined in this area. Typically, for a pad block, there are one output wiring and one input wiring.

The RAM block 1202 typically has about 1 megabyte, In this wiring, priority is given to a fine structure over a speed, and there is a need of the narrowest wiring. The wide wiring is relatively little, and power source wirings and GND wirings are cyclically placed at a unit of a memory cell size.

The high performance logic block 1203 is a block, which has cells requiring a high drive performance and is a block where power source wirings are strengthened. Basically, this is close to a standard cell configuration of a gate array. Although the configuration of the wirings is similar to that of the RAM, the power source wirings are typically strengthened rather than that of the RAM. As compared with the PLL block, typically, there is a plurality of connections between the macro circuits.

In the PLL block 1204, priority is given to the stable operations of the power source, GND and capacitive elements. Thus, although the wiring density is low, typically, the wiring width is wide next to the I/O region. The PLL block amplifies a signal inputted from an external transmitter by 4 times or 5 times or the like, and constitutes a clock tree for each macro. The clock input unit and clock output unit of the PLL block serve as the lead-out wiring from the macro circuit. Basically, there are only two input/output wirings.

In this typical wiring placement structure, the block connection structure between two logic units is explained below. FIG. 7 is a schematic view showing the block connection structure between two logic units.

In FIG. 7, a reference letter 1301 indicates a first logic region (macro circuit region), a reference letter 1302 indicates a second logic region (macro circuit region), and a reference letter 1303 indicates a region between the macro circuits. Power source lines 1304 and GND lines 1305 are placed inside the macro. Signal lines 1306 are placed between the power source line 1304 and the GND line 1305 inside the macro. Moreover, this signal line 1306 connects the macro in the first logic region 1301 and the macro in the second logic region 1302. A reference letter 1307 indicates the connection region between those signal lines. There is a case that the lines between the macros in the same wiring layer are connected, or there is a case that the lines between the macros in the different wiring layers are connected.

FIG. 8 is an enlarged schematic view showing the connection region 1307 between the signal lines. In FIG. 8, a reference letter 1401 indicates a macro region, and a reference letter 1402 indicates the boundary region between the macros. A signal lead-out wiring 1403 is connected from the boundary region 1402 to the macro region 1401. Inside the macro region 1401, there are a power source line 1404 and a GND line 1405. Between the power source line 1404 and the GND line 1405, there are locally signal lines 1406. One of them is connected to the lead-out wiring 1403. The signal line 1406 is typically used in the minimum dimensional wiring in the macro circuit. Vias 1407 exist in the macro region 1401.

However, we have now discovered the following facts. Typically, the largest wiring area per unit area (the highest wiring data rate) is used for the lead-out wiring and the pad wiring in the pad and so on, in the case of the test pattern for the wiring process evaluation. In the case of the typical product, the largest wiring area per unit area (the widest wiring) is used for the power source wiring or the wiring in the I/O block or the like. In these regions, the drop in the wiring area per unit area (the wiring data rate) leads to the drop in-the number of the vias, and consequently reduces the product specification because of dropping the number of the vias which limit the reliability. On the other hand, in the fine wiring process in the same wiring layer, the fact that there are the wiring portion with the wide wiring width and the region with the high wiring data rate results in the great obstacle on the process. For example, although the wiring with the wide width can be short in exposure time, the wiring with the fine width is long in the exposure time. The longer exposure time causes the narrow portion to be induced between the wiring with a large area and the fine wiring adjacent thereto. In short, since the optimal exposure light intensity is different in accordance with a mask open area, there is a problem that the process margin of the photolithography cannot be secured for the entire pattern of the same wiring layer.

### SUMMARY OF THE INVENTION

In order to achieve an aspect of the present invention, the present invention provides a semiconductor device including; a first wiring portion configured to include a plurality of fine wirings placed densely; and a second wiring portion configured to include a wiring, which is connected to one of the plurality of fine wirings in the same wiring layer, and of which outside dimension is larger than that of the one of the plurality of fine wirings, wherein the wiring of the second wiring portion is composed of a peripheral wiring which circles an outer periphery of the wiring.

In the present invention, even though the outside dimension of the wiring in the second wiring portion is larger than that of the fine wiring in the first wiring portion, the wiring in the second wiring portion is composed of a peripheral wiring which circles an outer periphery of the wiring. That is, the substantive width of the wiring is equal to the width of the peripheral wiring. Since the width of the peripheral wiring is narrower and closer to that of the fine wiring than the outside dimension, the optimal exposure condition common in the entire pattern can be secured in the photolithography process for the pattern with the first and second wiring portions.

### BRIEF DESCRIPTION OF THE DRAWINGS

The above and other objects, advantages and features of the present invention will be more apparent from the following description taken in conjunction with the accompanying drawings, in which:

FIG. 1 is a schematic view showing a test chip layout for a typical process evaluation;

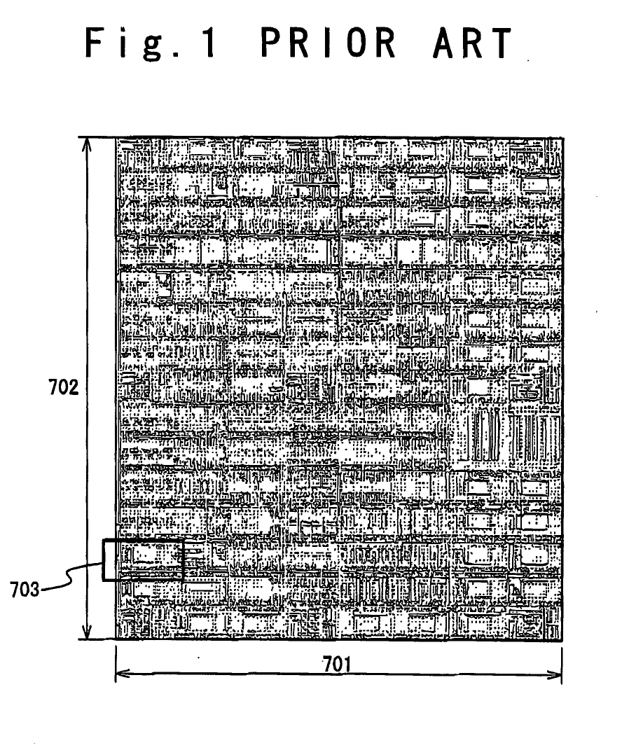

FIG. 2 is a schematic view showing a connection region between a TEG region and an electrode pad;

FIG. 3 is a graph showing a relation between a wiring width (CD) and a wiring pitch;

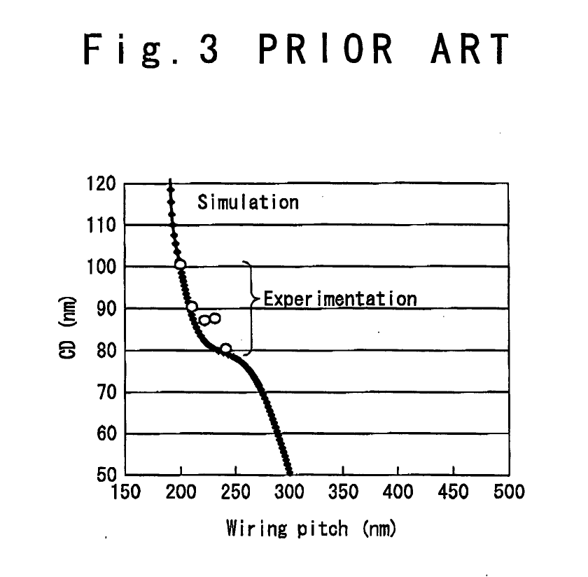

FIG. 4 is an enlarged schematic plan view showing a lead-out wiring and a TEG region in a test pattern for a conventional via chain evaluation;

FIGS. 5A to 5E are schematic sectional views showing a process for manufacturing a typical two-layer wiring;

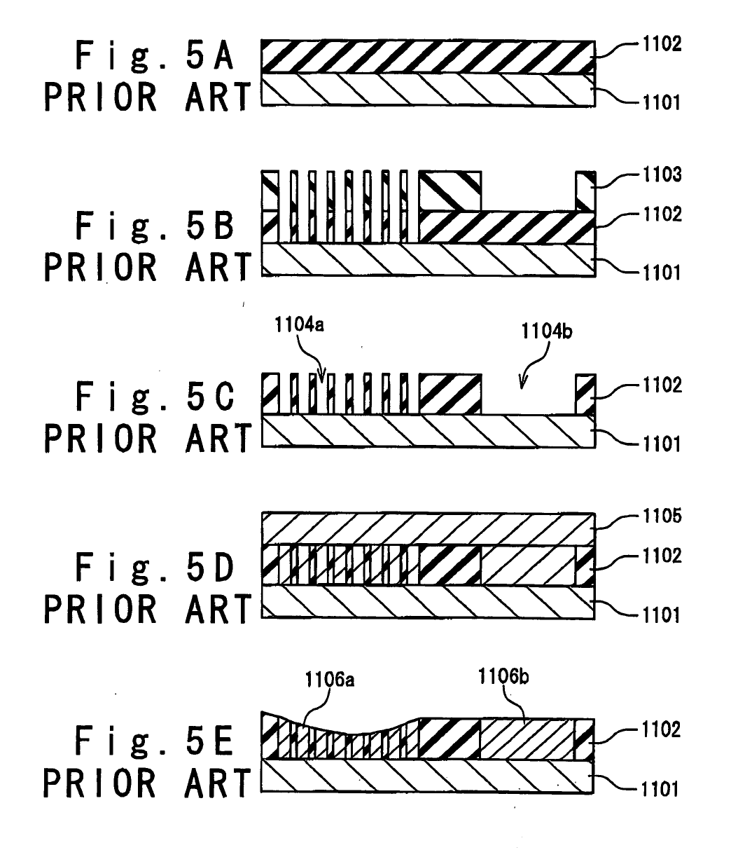

FIG. 6 is a schematic plan view showing a typical product;

FIG. 7 is a schematic plan view showing a connection structure between two macro blocks;

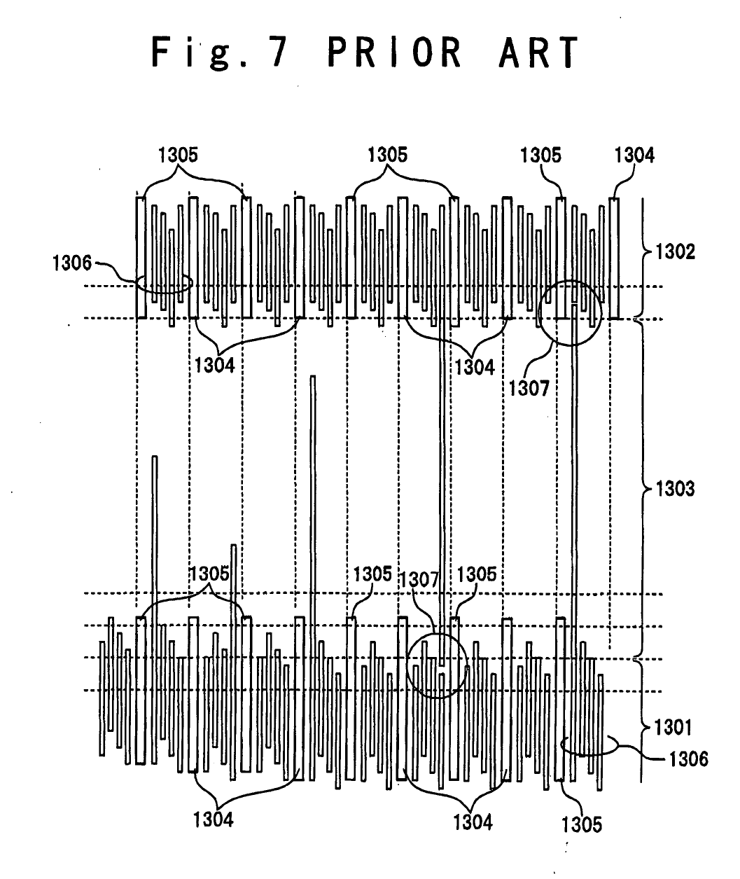

FIG. 8 is an enlarged schematic view showing a connection region between signal lines in FIG. 7;

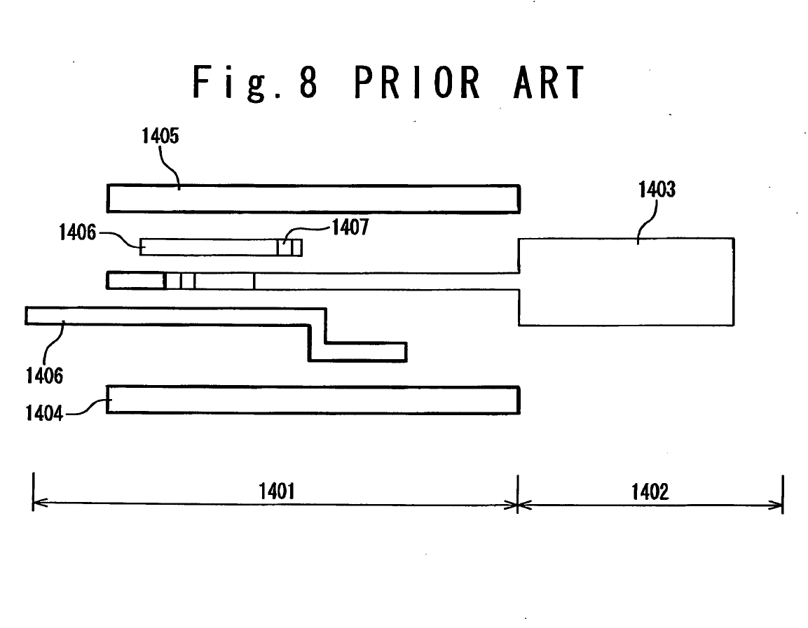

FIG. 9 is an enlarged schematic plan view showing a TEG region and a lead-out wiring extended from this TEG to a pad according to the first embodiment of the present invention;

FIG. 10 is a graph showing a relation between a cycling wiring width in a lead-out wiring region and a distance between the lead-out wiring and a macro;

FIG. 11 is an enlarged schematic plan view showing a TEG region and a pad connected to a lead-out wiring from the TEG according to the second embodiment of the present invention;

FIG. 12 is a graph showing the relation between a cycling wiring width in a pad portion and a distance between the pad portion and the macro;

FIG. 13 is a graph showing the comparison between the data rate of the second embodiment and that of the conventional example, which have the various device configuration elements;

FIG. 14 is a graph showing a relation between the variation in the data rate of the data configuration element and a process margin of a photolithography; and

FIG. 15 is a schematic enlarged view showing an example of a connection region to a signal wiring in a product according to the third embodiment of the present invention.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Embodiments of a semiconductor device, a method of forming a wiring pattern, and a method of generating mask wiring data according to the present invention will be described below with reference to the attached drawings.

(First Embodiment)

This embodiment indicates a method that can reduce a data rate of a wiring, with regard to a lead-out wiring used for an electric evaluation such as a wiring resistance and the like. In the case of the test pattern for the wiring process evaluation, typically, the largest wiring area per unit area (the highest wiring data rate) is used for the pad wiring. In this wiring region, the drop in the wiring area per unit area (the wiring data rate) leads to the drop in the number of the vias, and consequently reduces the product specification because of dropping the number of the vias which limit the reliability. On the other hand, in the fine wiring process, the fact that there are the wiring portion with the wide wiring width and the region with the high wiring data rate results in the great obstacle on the process. Therefore, this embodiment proposes a method that effectively reduces the substantive wiring width and the wiring area per unit area (the wiring data rate) on the basis of a conventional design data, so as to be able to secure an exposure condition which is common in all of the patterns in the same wiring layer.

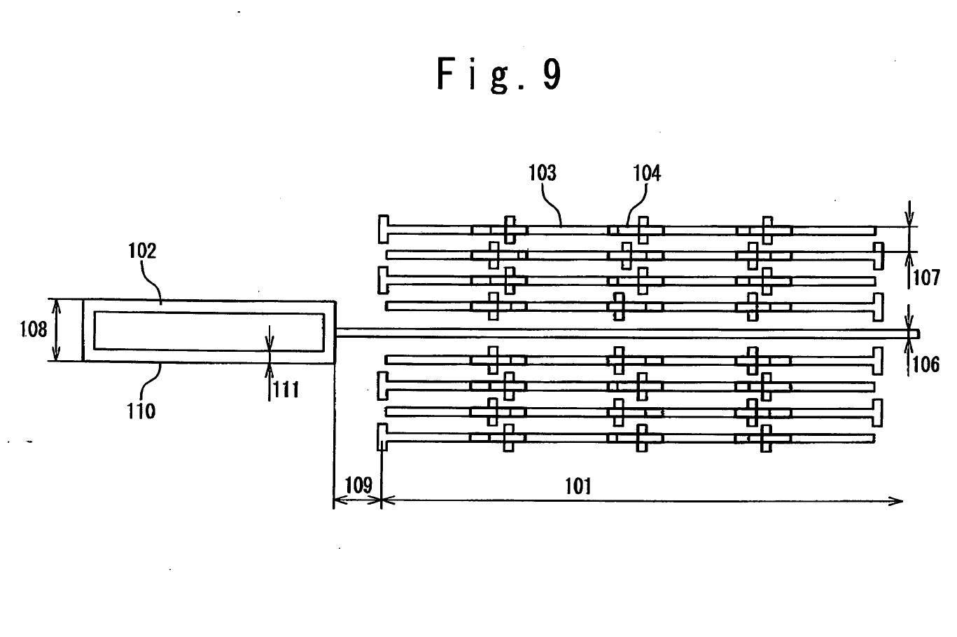

FIG. 9 is an enlarged schematic plan views showing a TEG region and a lead-out wiring extended from this TEG to a pad, as a first embodiment.

The test pattern includes: a via chain evaluation TEG region 101 corresponding to a macro circuit region; and a lead-out wiring 102 through which the TEG region 101 is electrically connected to the pad (not shown). The via chain portion formed in the TEG region 101 is configured such that M1 wirings (first layer wirings) 103 and M2 wirings (second layer wirings) 104 are alternately placed in a lower layer and an upper layer, respectively, and those wirings are connected through vias (not shown). Here, both of widths of the M1 wiring 103 and the M2 wring 104 are 70 nm that is the minimum wiring width 106. The via chain is placed in a wiring pitch 107. An entire width 108 of the lead-out wiring 102 isolated outside the TEG region 101 is 0.3 μm (micrometer). The lead-out wiring 102 is connected in the same wiring layer to one M1 wiring 103 inside the TEG region 101. Incidentally, a reference letter 109 indicates a connection distance between the portion of the lead-out wiring 102 and the TEG region 101.

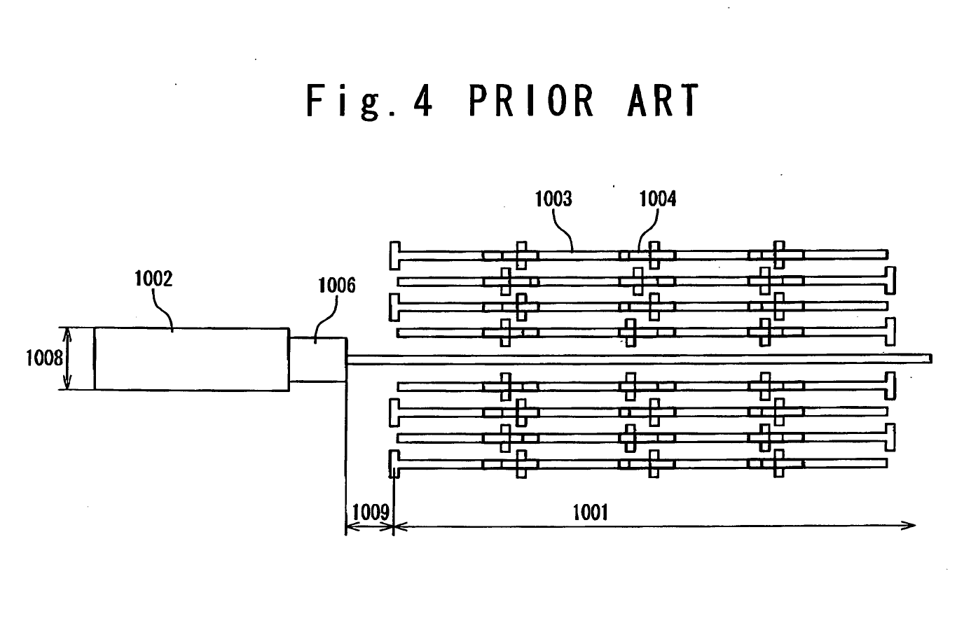

The lead-out wiring 102 is constituted by a wiring (hereafter, referred to as a cycling wiring) 110 such that the wiring circles only the outer periphery of a conventional lead-out wiring (such as wiring 1002, 1006 in FIG. 4). When a via is formed for the lead-out wiring 102, it is formed in the portion of the cycling wiring 110.

The effect of this embodiment is described below.

It is possible to reduce the substantive wiring width and a wiring area per unit area (the wiring data rate), without performing the design change of the outer shape in the connecting wiring portion between the lead-out wiring and the TEG macro in the same wiring layer, by deleting the area (data) inside the lead-out wiring while the area (data) in the outer peripheral portion is left. This has a merit that, since the wiring width of the cycling wiring is changed to be narrower, the suitable process margin is secured, and the wiring area per unit area (the wiring data rate) can be reduced while the conventional design data is used. In particular, conventionally, the wiring whose width is changed in the stepped manner is used in the connection region between the TEG macro and the lead-out wiring. However, according to the present invention, without any use of such wirings, the area of the wiring (the wiring data) can be generated by the combination of simple rectangles. Consequently, this has the merit of improving the integration degree, because it is possible to decrease the data amount and further possible to make the interval between the lead-out wiring and the TEG macro short.

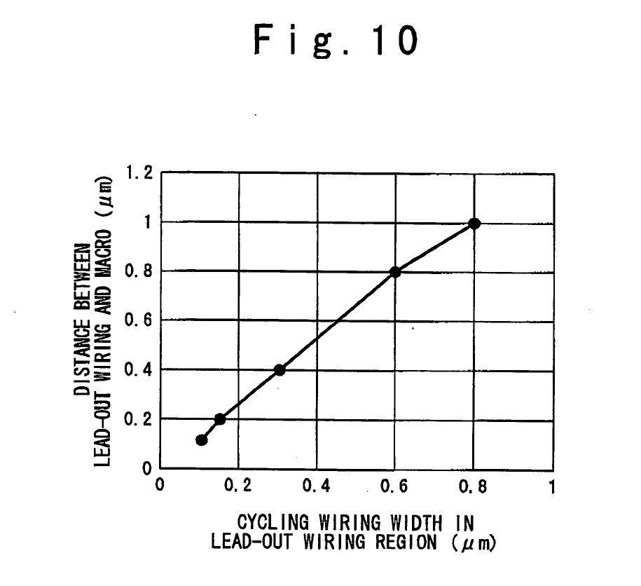

Here, the relation between the wiring width 111 of the cycling wiring 110 and the interval (the connection distance 109) between the lead-out wiring 110 and the TEG macro is explained below. FIG. 10 is a graph showing the relation between the wiring width 111 and the connection distance 109. The horizontal axis shows the wiring width 111 and the vertical axis shows the connection distance 109. As can be seen in FIG. 10, as the wiring width 111 is made narrower, the connection distance 109 can be made narrower. For example, when the wiring width 111 is 0.15 μm (micrometer), the connection distance 109 can be made close to about 0.2 μm, and in a case of 0.12 μm of the wiring width 111, the connection distance 109 can be made close up to 0.15 μm.

Based on the above description, a method of forming a wiring pattern according to the present invention will be described below.

The method of forming the wiring pattern includes the steps of (a) and (b). The step (a) is the step of providing an existing pattern for wirings. Here, the wirings includes: a first wiring portion (e.g. 101) configured to have a plurality of fine wirings (e.g. 103 and 104) placed densely, and a second wiring portion configured to include a wiring (e.g. 102), which is connected to one of the plurality of fine wirings (e.g. 103) in the same wiring layer (e.g. M1), and of which outside dimension (e.g. 108) is larger than that (e.g. 106) of the one of the plurality of fine wirings (e.g. 103).

The step (b) is the step of forming a peripheral wiring (e.g. 110) which circles an outer periphery of the wiring (e.g. 102) of the second wiring portion by remaining the outer periphery of the wiring (e.g. 102) while removing an inside of the outer periphery of the wiring (e.g. 102).

Based on the above description, a method of generating a mask wiring data according to the present invention will be described below.

The method of generating the mask wiring data includes the steps of (a) and (b). The step (a) is the step of providing an existing mask wiring data for wirings. Here, the wirings includes: a first wiring portion (e.g. 101) configured to have a plurality of fine wirings (e.g. 103 and 104) placed densely, and a second wiring portion configured to include a wiring (e.g. 102), which is connected to one of the plurality of fine wirings (e.g. 103) in the same wiring layer (e.g. M1), and of which outside dimension is larger than that (e.g. 106) of the one of the plurality of fine wirings (e.g. 103).

The step (b) is the step of forming a mask wiring data having a data for a peripheral wiring (e.g. 110) by remaining data for an outer periphery of the wiring (e.g. 102) while removing data for an inside of the outer periphery of the wiring (e.g. 102).

(Second Embodiment)

This embodiment is an example of reducing the wiring area per unit area (the data rate) of a square pad with which an electrically measuring needle (probe) used for a wiring process evaluation is brought into contact.

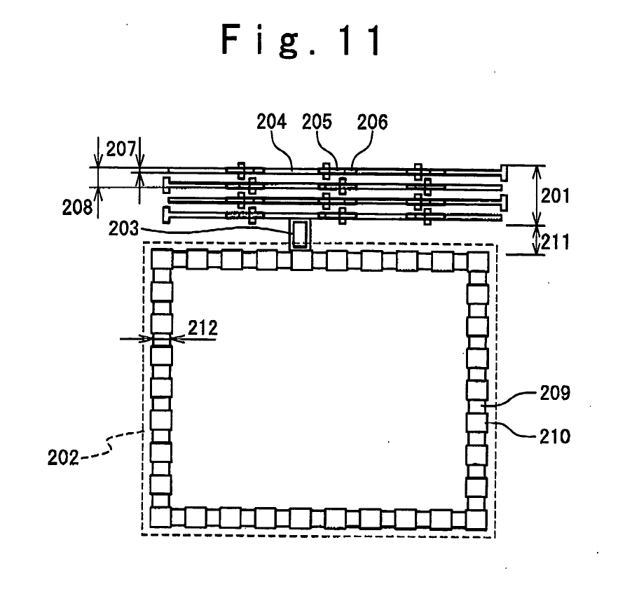

FIG. 11 is a enlarged schematic plan view showing a TEG region and a pad connected to the lead-out wiring from this TEG, as a second embodiment.

The test pattern includes: a via chain evaluation TEG region 201; a pad portion 202 with which the electrically measuring needle (probe) is brought into contact; and a lead-out wiring 203 through which the pad portion 202 is electrically connected to the wiring inside the TEG region 201. The via chain portion formed in the TEG region 201 is configured such that M1 wirings (first layer wirings) 204 and M2 wirings (second layer wirings) 205 are alternately placed in a lower layer and an upper layer, and those wirings are connected through vias (V1s) 206. Here, both of widths of the M1 wiring 204 and the M2 wring 205 are 70 nm that is the minimum wiring width 207. The via chain is placed in a wiring pitch 208.

The lead-out wiring 203 outside the TEG region 201 is connected in the same wiring layer to the predetermined M1 wring 204 inside the TEG region 201. The lead-out wiring 203 is constituted by the cycling wiring similar to the first embodiment.

In the region of the pad portion 202, a wiring (hereafter, referred to as a cycling wiring) 209 is formed such that the wiring cycles only the outer periphery of the pad portion 202. The cycling wiring 209 is formed in the same wiring layer as the M1 wiring 204 and the lead-out wiring 203 and connected to the lead-out wiring 203. Moreover, on the cycling wiring 209, a plurality of pad vias (V1s) 210 are placed along the cycling wiring 209.

Although not shown in the drawings, a M2 wiring are placed in the same configuration (structure) as the cycling wiring 209 on the plurality of pad vias (V1s) 210. A plurality of pad vias (V2s) are placed in the same configuration (structure) as the vias (V1s) 210 on the M2 wiring which is the cycling wiring. Then, M3 wirings (third layer wirings) of a square (grid-like) structure of 100 μm are placed on the plurality of pad vias (V2s). The M3 wirings function as the pad with which the electrically measuring needle (probe) can be brought into contact.

Incidentally, a reference letter 211 indicates a connection distance between the pad portion 202 and the TEG region 201.

The effect of this embodiment will be described below.

The first embodiment has the merit that the distance between the lead-out wiring and the TEG macro could be made narrow. On the contrary, this embodiment can reduce the distance between the pad portion and the TEG macro. As this result, the pad density can be increased and the inclusion amount of the process evaluation TEG can be increased. In short, the area of the TEG required to evaluate the process can be efficiently placed.

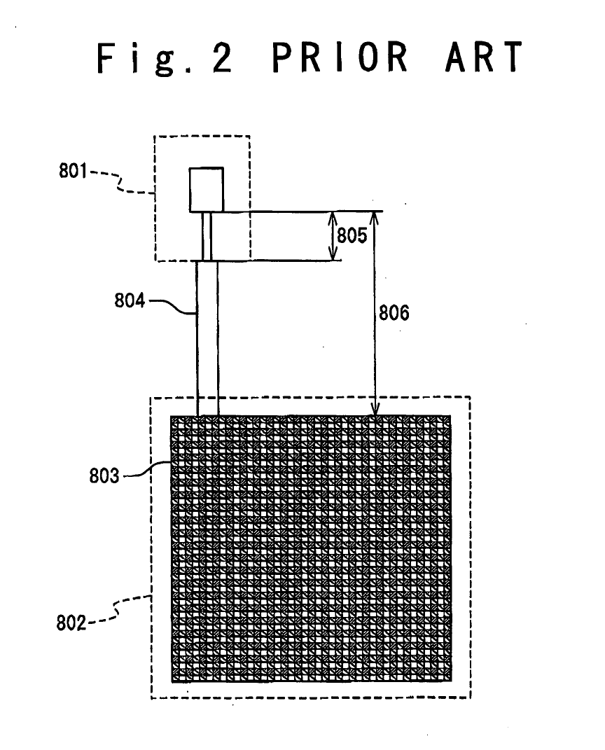

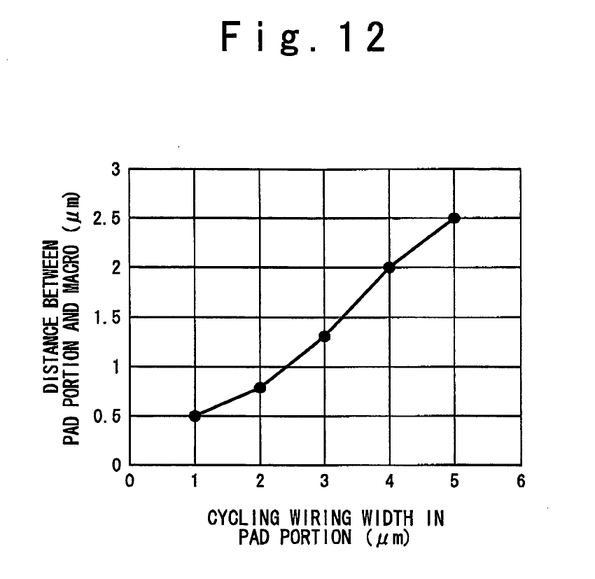

Here, the relation between a wiring width 212 of the cycling wiring 209 and the interval (the connection distance 211) between the pad portion 202 and the TEG region 201 is explained below. FIG. 12 is a view showing the relation between the wiring width 212 and the connection distance 211. The horizontal axis shows the wiring width 212 and the vertical axis shows the connection distance 211. However, this is the case that the pad has the shape of the square of 100 μm. As can be seen in FIG. 12, even if the wiring width 212 is 1 μm, the connection distance 211 can be made close up to 0.5 μm. This indicates that the interval can be greatly reduced, as compared with the case that the distance 806 between the TEG macro and the pad portion was about 50 μm in the conventional example of FIG. 2.

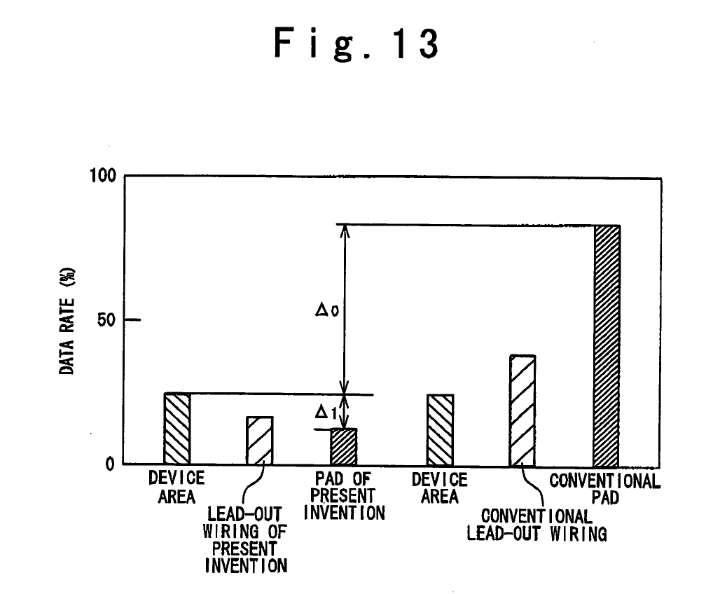

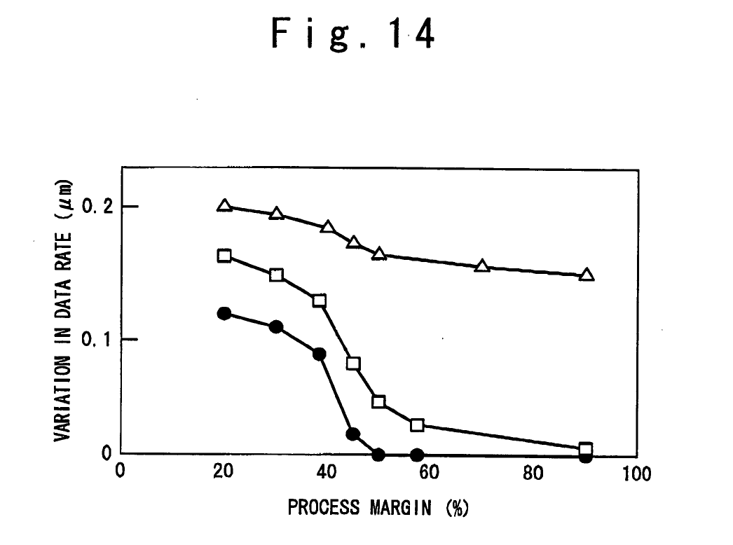

Moreover, the detail of the effect is described. FIG. 13 is a graph showing the comparison between the data rate of this embodiment and that of the conventional example, which have the various device configuration elements. The data rate corresponds to the wiring area per unit area. In the conventional process evaluation process (right side in FIG. 13), the respective data rates of the pad, the TEG macro and the lead-out wiring are greatly varied, and there is the difference of a maximum of about 60% (Δ0). However, as described in this embodiment, since the pad and the lead-out wiring are constituted by the cycling wiring, the data rates of the pad and the lead-out wiring can be greatly decreased, thereby decreasing the variation in the data rate to about 20% or less (Δ1). Also, from FIG. 13, it can be seen that the data rates of the lead-out wiring and the pad in this embodiment is limited to 50% or less, when the value equal to two times of the data rate of the device region is used as a basic data rate (reference) FIG. 14 is a graph showing the relation between the variation in the data rate and the process margin of the photolithography. The horizontal axis shows the variation in the data rate, and the vertical axis shows the process margin of the photolithography. The data rate corresponds to the wiring area per unit area. The triangle symbols show the case that the minimum width of wiring is 0.14 μm in the TEG macro. The square symbols show the case that the minimum width of wiring is 0.1 μm in the TEG macro. The circle symbols show the case that the minimum width of wiring is 0.70 nm in the TEG macro. The connection distance 211 is 1 μm. In FIG. 14, when the TEG macro is constituted by a plurality of fine wirings each of which has a width of 0.1 μm or less, if the variation in the data rate is 50% or more, both of the process margins of the pad region and the TEG macro where the plurality of fine wirings are densely crowded cannot be attained. Thus, the configuration applying the cycling wiring described in this embodiment to the pad and the lead-out wiring in order to reduce those data rates is effective for the enlargement of the process margin.

Based on the above description, a method of forming a wiring pattern according to the present invention will be described below.

The method of forming the wiring pattern includes the steps of (a) and (b). The step (a) is the step of providing an-existing pattern for wirings. Here, the wirings includes: a first wiring portion (e.g. 201) configured to have a plurality of fine wirings (e.g. 204 and 205) placed densely, and a second wiring portion (e.g. 211) configured to include a wiring (e.g. 203), which is connected to one (e.g. 204) of the plurality of fine wirings (e.g. 204 and 205) in the same wiring layer (e.g. M1), and of which outside dimension is larger than that (e.g. 207) of the one (e.g. 204) of the plurality of fine wirings (e.g. 204 and 205).

The step (b) is the step of forming a peripheral wiring which circles an outer periphery of the wiring of the second wiring portion (e.g. 211) by remaining the outer periphery of the wiring (e.g. 203) while removing an inside of the outer periphery of the wiring (e.g. 203).

The step (b) includes (b2) forming a second peripheral wiring (e.g. 209) which is connected to the peripheral wiring in the same wiring layer (e.g. M1), and circles an outer periphery of an area (e.g. 202) of a pad.

Based on the above description, a method of generating a mask wiring data according to the present invention will be described below.

The method of generating the mask wiring data includes the steps of (a) and (b). The step (a) is the step of providing an existing mask wiring data for wirings. Here, the wirings includes; a first wiring portion (e.g. 201) configured to have a plurality of fine wirings (e.g. 204 and 205) placed densely, and a second wiring portion (e.g. 211) configured to include a wiring (e.g. 203), which is connected to one (e.g. 204) of the plurality of fine wirings (e.g. 204 and 205) in the same wiring layer (e.g. M1), and of which outside dimension is larger than that (e.g. 207) of the one (e.g. 204) of the plurality of fine wirings (e.g. 204 and 205).

The step (b) is the step of forming a mask wiring data having a data for a peripheral wiring by remaining data for an outer periphery of the wiring (e.g. 203) while removing data for an inside of the outer periphery of the wiring (e.g. 203).

The step (b) includes (b2) forming the mask wiring data having a data for a second peripheral wiring (e.g. 209) which is connected to the peripheral wiring in the same wiring layer (e.g. M1), and circles an outer periphery of an area (e.g. 202) of a pad.

(Third Embodiment)

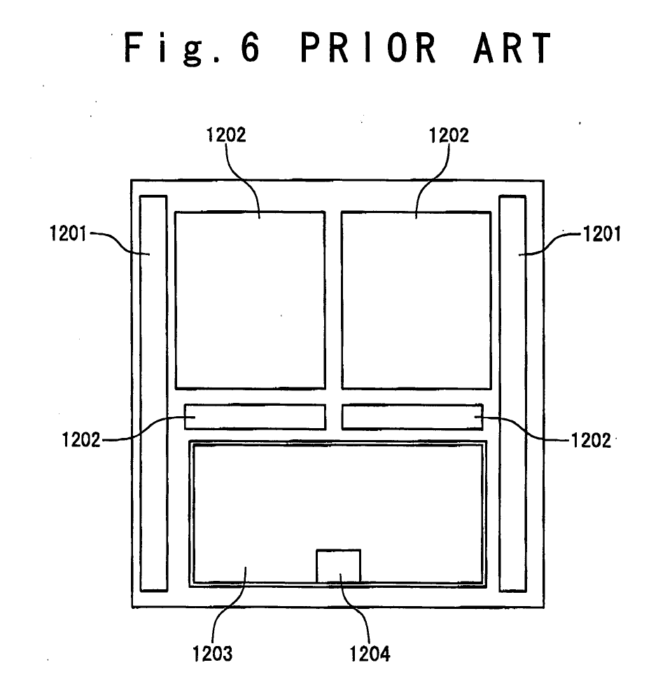

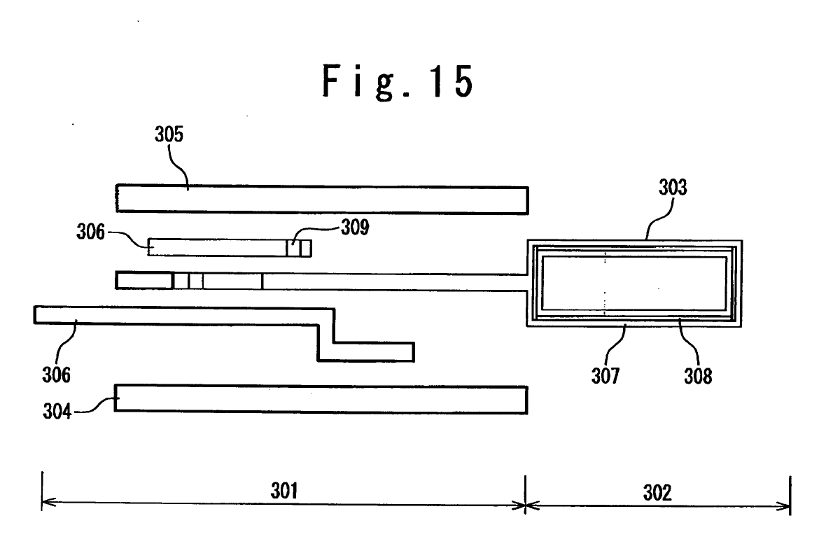

In this embodiment, the situation, in which the present invention is actually applied to a product, will be explained below with reference to FIG. 15. FIG. 15 is a schematic enlarged view showing an example of a connection region to a signal wiring in a product according to the third embodiment of the present invention. In FIG. 6, a reference letter 301 indicates a macro region, and a reference letter 302 indicates a boundary region between the macros. A lead-out wiring 303 for a signal is connected from the boundary region 302 to the macro region 301. A power source line 304 and a GND line 305 exist inside the macro region 301. Between the power source line 304 and the GND line 305, there are signal wirings 306, and one of them is connected to the lead-out wiring 303. Typically, the signal line 306 is used in the minimum dimensional wiring in the macro circuit. Vias 309 exist in the macro region 301.

Here, the lead-out wiring 303 is constituted by a wiring 307 circling along only the outer periphery of the lead-out wiring. Also, on the cycling wiring 307, a via 308 for a connection to wirings (not shown) in an upper layer is formed long and continuously along the wiring 307. In short, the via 308 is formed similarly to the shape of the cycling wiring 307. Incidentally, although in FIG. 15, the width of the via 308 is designed to be narrower than the width of the wiring 307, both of the widths may be equal.

The effect of this embodiment will be described below.

This embodiment indicates that even in the product, the cycling wiring can be applied to the lead-out wiring and further has the effect that since the via is formed such as the wiring, the via resistance can be decreased. Such a via (hereafter, referred to as a slit via) is especially effective for the device function portion in which the I/O block requires a high current density. Also, the configuration that the substantial volume of a copper wiring is secured by making the width of the slit via equal to the wiring width can compensate the wiring width reduction caused by the fine wiring. Thus, this is the technique indispensable to improve the reliability and stabilize the voltage variation.

Based on the above description, a method of forming a wiring pattern according to the present invention will be described below.

The method of forming the wiring pattern includes the steps of (a) and (b). The step (a) is the step of providing an existing pattern for wirings. Here, the wirings includes: a first wiring portion (e.g. 301) configured to have a plurality of fine wirings (e.g. 306) placed densely, and a second wiring portion (e.g. 302) configured to include a wiring (e.g. 303), which is connected to one of the plurality of fine wirings (e.g. 306) in the same wiring layer (e.g. M1), and of which outside dimension is larger than that of the one (e.g. 306) of the plurality of fine wirings (e.g. 306).

The step (b) is the step of forming a peripheral wiring (e.g. 307) which circles an outer periphery of the wiring (e.g. 303) of the second wiring portion (e.g. 302) by remaining the outer periphery of the wiring (e.g. 303) while removing an inside of the outer periphery of the wiring (e.g. 303).

The step (b) includes (b1) forming a via (e.g. 308) which is long and continuously along on the peripheral wiring (e.g. 307).

Based on the above description, a method of generating a mask wiring data according to the present invention will be described below.

The method of generating the mask wiring data includes the steps of (a) and (b). The step (a) is the step of providing an existing mask wiring data for wirings. Here, the wirings includes: a first wiring portion (e.g. 301) configured to have a plurality of fine wirings (e.g. 306) placed densely, and a second wiring portion (e.g. 302) configured to include a wiring (e.g. 303), which is connected to one (e.g. 306) of the plurality of fine wirings (e.g. 306) in the same wiring layer (e.g. M1), and of which outside dimension is larger than that of the one (e.g. 306) of the plurality of fine wirings (e.g. 306).

The step (b) is the step of forming a mask wiring data having a data for a peripheral wiring (e.g. 307) by remaining data for an outer periphery of the wiring (e.g. 303) while removing data for an inside of the outer periphery of the wiring (e.g. 303).

The step (b) includes (b1) forming the mask wiring data having a data for a via (e.g. 308) formed long and continuously along on the peripheral wiring (e.g. 307).

In the present invention, the above-mentioned method of forming a wiring pattern and method of generating the mask wiring data of all the embodiments are executed by the computer such as a workstation and a personal computer. Here, the computer includes the programs that can execute the above-mentioned method of forming a wiring pattern and method of generating the mask wiring data.

According to the present invention, the optimal exposure condition common in the entire pattern can be secured, in the photolithography process of the pattern that is provided with: the region in which the plurality of fine wirings are densely crowded, and the wiring portion which is larger in outer dimension than the fine wiring connected in the same wiring layer to the predetermined fine wiring in this area.

It is apparent that the present invention is not limited to the above embodiment that may be modified and changed without departing from the scope and spirit of the invention.

What is claimed is:

1. A semiconductor device comprising:
a first wiring portion configured to include a plurality of fine wirings placed densely; and
a second wiring portion configured to include a wiring, which is connected to one of said plurality of fine wirings in the same wiring layer, and of which outside dimension is larger than that of said one of said plurality of fine wirings,
wherein said wiring of said second wiring portion is composed of a peripheral wiring which circles an outer periphery of said wiring.

2. The semiconductor device according to claim 1, wherein a data rate of said second wiring portion is limited to 50% or less, when a value equal to two times of said data rate of said first portion is used as a basic data rate.

3. The semiconductor device according to claim 1, wherein a wiring width of each of said plurality of fine wirings is equal to 0.1 μm or less.

4. The semiconductor device according to claim 1, wherein said second wiring portion further includes;
a via which is formed long and continuously along on said peripheral wiring.

5. The semiconductor device according to claim 1, wherein said second wiring portion further includes:
a second peripheral wiring which is connected to said peripheral wiring in the same wiring layer, circles an outer periphery of an area of a pad, and is connected to said pad through vias on said second peripheral wiring.

6. The semiconductor device according to claim 1, wherein said wiring of said second wiring portion is a lead-out wiring, and said first wiring portion is included in a macro.

7. The semiconductor device according to claim 1, wherein said wiring of said second wiring portion is a lead-out wiring, and said first wiring portion is included in a TEG (Test Element Group).

8. A method of forming wiring pattern comprising:
(a) providing an existing pattern for wirings, wherein said wirings includes:
a first wiring portion configured to include a plurality of fine wirings placed densely, and
a second wiring portion configured to include a wiring, which is connected to one of said plurality of fine wirings in the same wiring layer, and of which outside dimension is larger than that of said one of said plurality of fine wirings; and
(b) forming a peripheral wiring which circles an outer periphery of said wiring of said second wiring portion by remaining said outer periphery of said wiring while removing an inside of said outer periphery of said wiring.

9. The method of forming wiring pattern according to claim 8, wherein said step (b) includes:
(b1) forming a via which is long and continuously along on said peripheral wiring.

10. The method of forming wiring pattern according to claim 8, wherein said step (b) includes:
(b2) forming a second peripheral wiring which is connected to said peripheral wiring in the same wiring layer, and circles an outer periphery of an area of a pad.

11. A method of generating mask wiring data comprising:
(a) providing an existing mask wiring data for wirings, wherein said wirings includes:
a first wiring portion configured to include a plurality of fine wirings placed densely, and
a second wiring portion configured to include a wiring, which is connected to one of said plurality of fine wirings in the same wiring layer, and of which outside dimension is larger than that of said one of said plurality of fine wirings; and
(b) forming a mask wiring data having a data for a peripheral wiring by remaining data for an outer periphery of said wiring while removing data for an inside of said outer periphery of said wiring.

12. The method of generating mask wiring data according to claim 11, wherein said step (b) includes;
(b1) forming said mask wiring data having a data for a via formed long and continuously along on said peripheral wiring.

13. The method of generating mask wiring data according to claim 11, wherein said step (b) includes:
(b2) forming said mask wiring data having a data for a second peripheral wiring which is connected to said peripheral wiring in the same wiring layer, and circles an outer periphery of an area of a pad.
